(19) United States
(12) Patent Application Publication
(10) Pub. No.: US 2025/0125187 A1
(43) Pub. Date: Apr. 17, 2025

(54) METHODS FOR MAKING SEMICONDUCTOR TRANSISTOR DEVICES WITH RECESSED SUPERLATTICE OVER WELL REGIONS

(71) Applicant: ATOMERA INCORPORATED, LOS GATOS, CA (US)

(72) Inventors: DONGHUN KANG, SAN JOSE, CA (US); KEITH DORAN WEEKS, CHANDLER, AZ (US); DANIEL CONNELLY, SAN FRANCISCO, CA (US); HIDEKI TAKEUCHI, SAN JOSE, CA (US); ROBERT J. MEARS, WELLESLEY, MA (US)

(21) Appl. No.: 18/915,565

(22) Filed: Oct. 15, 2024

Related U.S. Application Data
(60) Provisional application No. 63/590,559, filed on Oct. 16, 2023.

(51) Int. Cl. H01L 21/762; H01L 21/02; H01L 21/265; H01L 21/3065; H01L 21/308; H01L 21/8238; H01L 29/66

(52) U.S. Cl. CPC H01L 21/76237; H01L 21/02057; H01L 21/26513; H01L 21/3065; H01L 21/3083; H10D 30/0223; H10D 84/0188; H10D 84/038

(57) ABSTRACT

A method for making a semiconductor device may include forming spaced apart shallow trench isolation (STI) regions in a semiconductor layer, etching first portions of the semiconductor layer between adjacent ones of the STI regions to an etch depth, and performing a well implant in the first portions of the semiconductor layer. The method may further include forming respective superlattices on the first portions of the semiconductor layer between the adjacent ones of STI regions and with a height not greater than the etch depth. The method may also include forming respective spaced apart source and drain regions associated with each superlattice, and forming a respective gate above each superlattice.

### RELATED APPLICATIONS

This application claims the benefit of U.S. provisional application Ser. No. 63/590,559 filed Oct. 16, 2023, which is hereby incorporated herein in its entirety by reference.

### TECHNICAL FIELD

The present disclosure generally relates to semiconductor devices, and, more particularly, to approaches for fabricating semiconductor devices with enhanced semiconductor materials.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a semiconductor device may include forming spaced apart shallow trench isolation (STI) regions in a semiconductor layer, etching first portions of the semiconductor layer between adjacent ones of the STI regions to an etch depth, and performing a well implant in the first portions of the semiconductor layer. The method may further include forming respective superlattices on the first portions of the semiconductor layer between the adjacent ones of STI regions and with a height not greater than the etch depth. Each superlattice may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions. The method may also include forming respective spaced apart source and drain regions associated with each superlattice, and forming a respective gate above each superlattice.

In an example implementation, each superlattice may define a channel region between adjacent ones of the source and drain regions. In some implementations, the method may further include forming a mask over at least some of the STI regions and second portions of the semiconductor layer prior to etching. The method may also include forming respective first oxide portions over the superlattices, and forming respective second oxide portions over the second portions of the semiconductor layer, with the second oxide portions being thicker than the first oxide portions. By way of example, the etch depth may be 60 nm or less.

In some embodiments, the method may also include growing a respective semiconductor buffer layer in each of the etched portions of the semiconductor layer after performing the well implant. The method may additionally include performing another well implant in the semiconductor buffer layers prior to forming the superlattices. In some implementations, the method may include performing a post etch cleaning after etching. By way of example, etching may include reactive ion etching. Also by way of example, the base semiconductor monolayers may comprise silicon, and the at least one non-semiconductor monolayer may comprise oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIGS. 4A-4E are a series of schematic cross-sectional diagrams illustrating a method of making a semiconductor device with superlattice epitaxial growth after recess etching and well implant in accordance with an example embodiment.

FIGS. 5A and 5E are schematic cross-sectional diagrams of an example semiconductor device fabricated using the method of FIGS. 4A-4E.

FIGS. 6A-6C are a series of cross-sectional diagrams illustrating an alternative approach to the step illustrated in FIG. 4D.

FIGS. 7A-7B are a series of cross-sectional diagrams illustrating yet another alternative approach to the step illustrated in FIG. 4D.

FIGS. 8A-8E are a series of schematic cross-sectional diagrams illustrating an alternative embodiment to the method of FIGS. 4A-4E.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

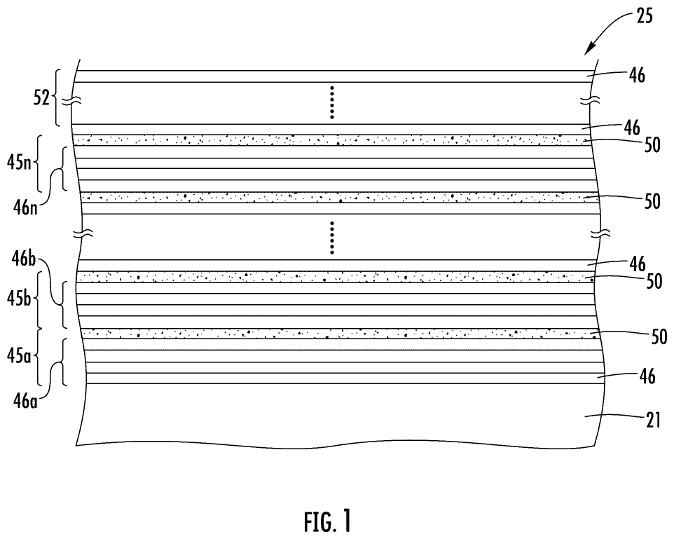

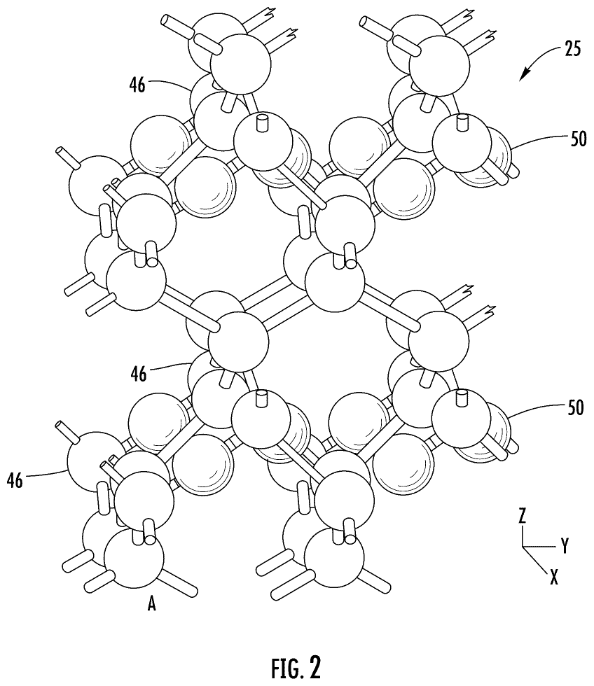

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

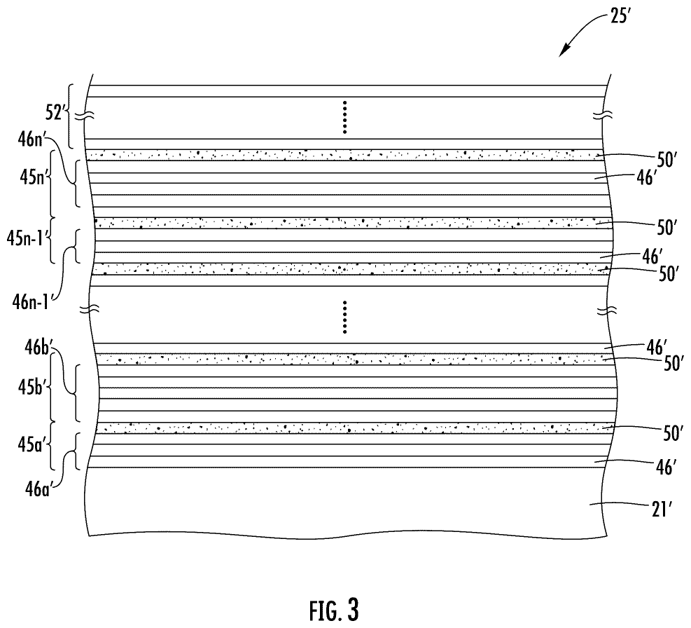

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

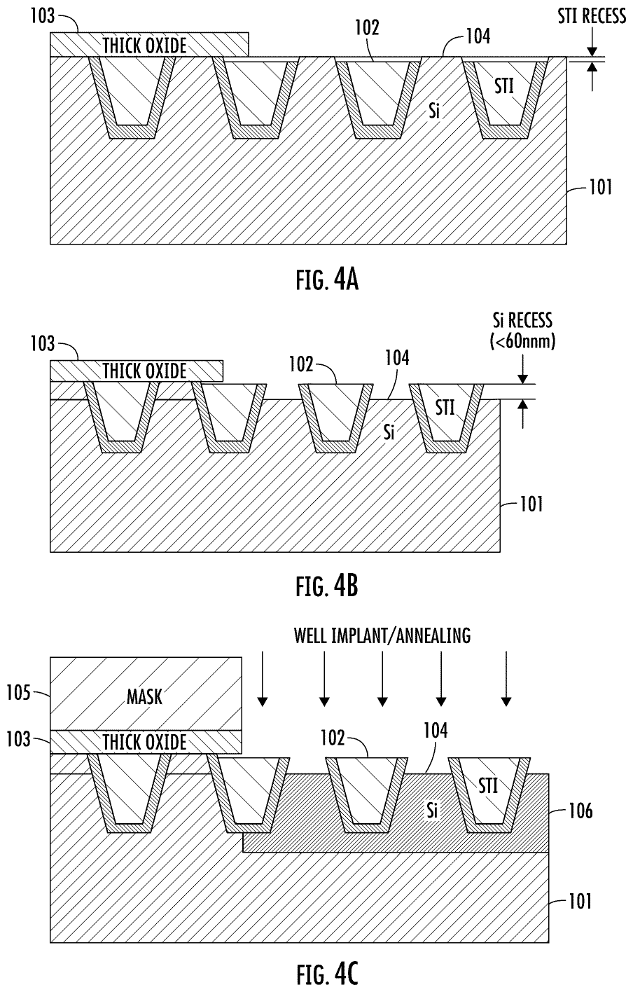

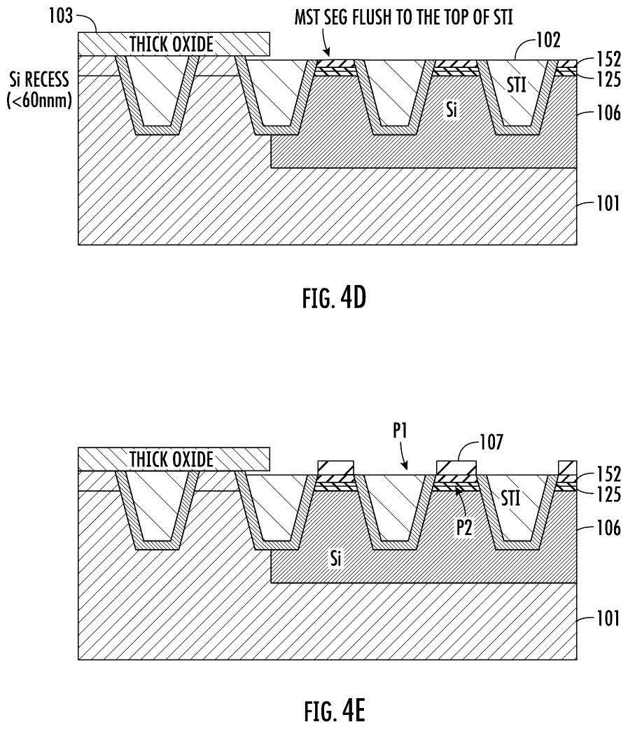

Turning to FIGS. 4A-4E, an approach for fabricating MST films 125 in the channel region of semiconductor transistors 100 between adjacent shallow trench isolation (STI) regions 102 is now discussed. In this regard, after STI regions 102 are formed in a semiconductor (e.g., silicon) substrate or layer 101, the upper surface of the silicon between the STI regions may not be flat. In such cases, forming an MST layer 125 on this surface may result in the upper surface of an STI region 102 being below the bottom of the adjacent MST layer 125, which may result in leakage, for example. However, it may not be possible to change the incoming STI step height in certain process flows.

To overcome these technical challenges, the present approach advantageously provides for a change in the well implantation step after silicon recess etching. In some implementations, this approach may be used to create a FINFET saddled in a DRAM cell transistor, for example, as well as other device configurations, as will be appreciated by those skilled in the art.

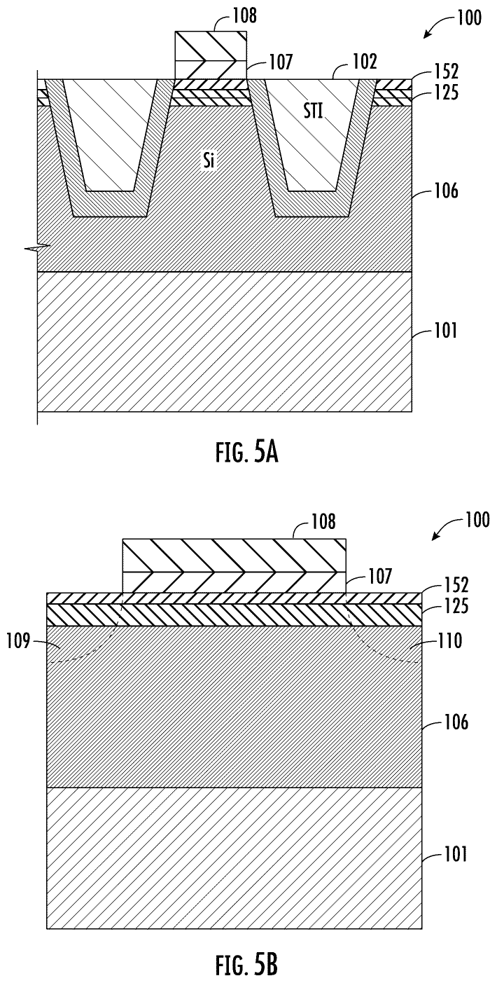

In the present approach, after the spaced apart STI regions 102 are formed, the resulting thick oxide region 103 above the STI regions is removed in the desired locations to expose selected localized silicon regions 104. A dry clean may optionally be performed to remove any native oxide from the silicon regions 104. The silicon regions 104 are then etched (e.g., using Cl₂) to a desired recess depth (FIG. 4B), which in the present example is 60 nm or less, although different etch depths may be used in different embodiments. One of several variations may then be used for the well formation. In the example shown in FIGS. 4C-4D, a mask 105 is formed over the thick oxide regions 103, and a well implant 106 is performed along with annealing. The MST films 125 and silicon cap 152 may then be formed by semiconductor epitaxial growth (SEG) within the localized region 104 of the silicon recesses, with or without a post growth anneal (PGA). Each of the MST films 125 may thereby be positioned to be flush or below the top of the adjacent STI regions 102 as shown. Gate oxide 107 preclean and growth may then be performed (FIG. 4E), followed by gate electrode 108 and source/drain regions 109, 110 formation, and the resulting device 100 is shown in FIGS. 5A and 5B (FIG. 5B is an orthogonal view to FIG. 5A). The MST film 125 position may be below the upper STI 102 surface (i.e., P1>P2 in FIG. 4E).

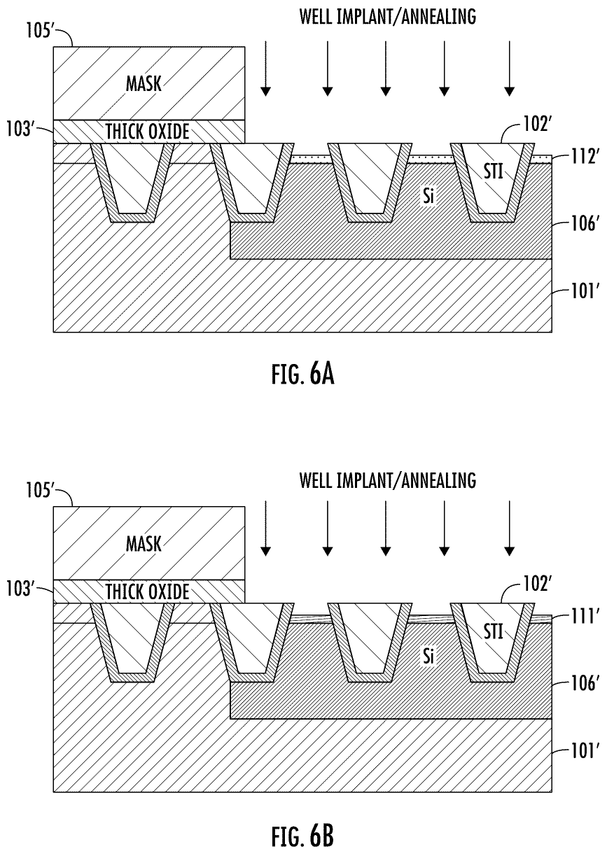

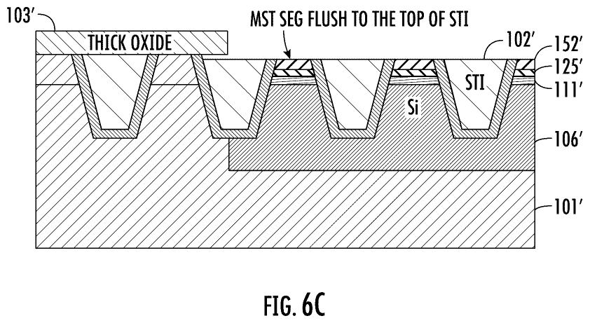

In accordance with another variation of the steps illustrated in FIGS. 4C-4D, referring now to FIGS. 6A-6C, after the recess etch a screen oxide 112′ is formed (FIG. 6A) prior to the well 106′ formation. By way of example, the screen oxide 112′ (e.g., SiO₂) may have a thickness of 10 nm or less. After the well 106′ implantation and anneal are completed, the screen oxide 112′ is removed and a silicon buffer 111′ is formed, followed by another well implant and annealing (FIG. 6B). By way of example, the silicon recess buffer may have a thickness of 10 nm or less, although different thicknesses may be used in different embodiments. The resulting MST layer segments 125′ are here again fabricated (FIG. 6C) to be flush with or below the upper surface of the adjacent STI regions 102′.

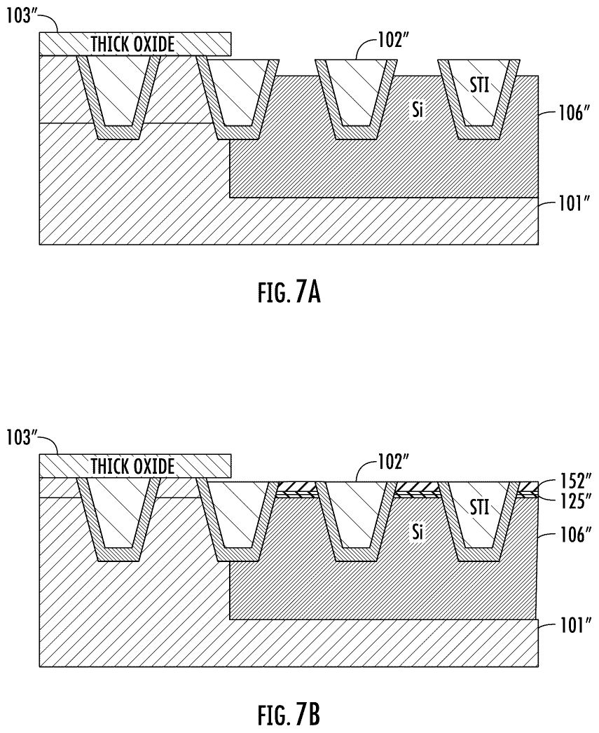

In yet another variation shown in FIGS. 7A-7B, in situ well 106″ growth is performed. More particularly, this may be done in the same processing chamber where the MST film 125″ growth occurs, which may advantageously reduce processing times/cost, for example.

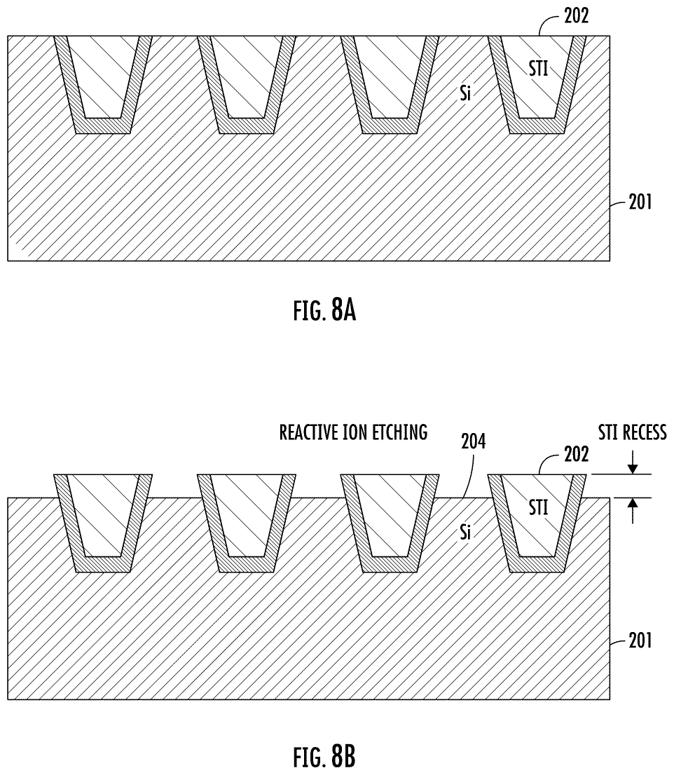

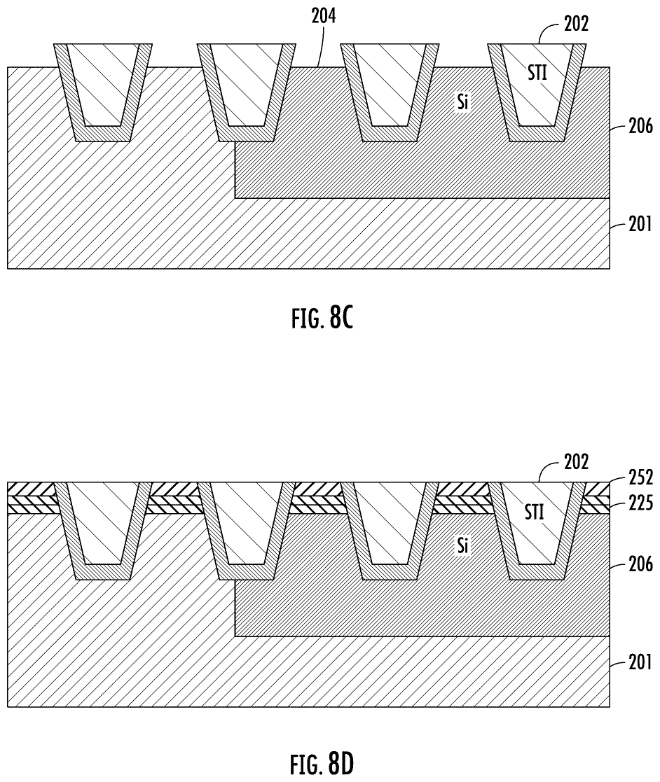

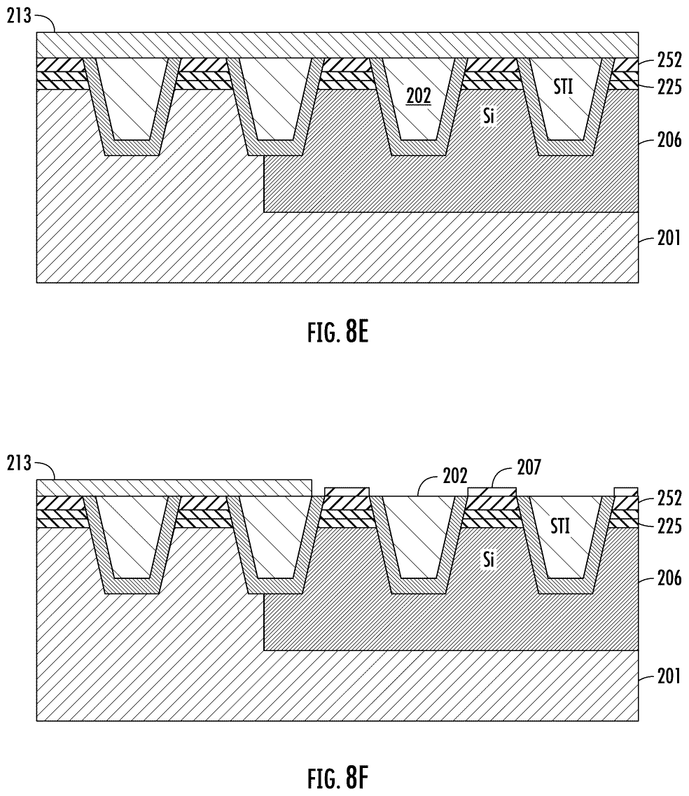

A second example process flow is now described with reference to FIGS. 8A-8F. After removal of the thick oxide (not shown) from the silicon wafer or layer 201, silicon recess etching (e.g., reactive ion etching, RIE) may be performed (e.g., HBR, ion etching, or a combination of these), as shown in FIG. 8B, to define localized regions 204. Here again, the etch depths may be similar to those described above in the first process flow. Next, one of the above-described well 206 implant variations is performed (e.g., implant (well)+annealing, Si buffer/implant (well)+annealing, or in situ well formation (in the same chamber with MST growth). MST film 225 and cap layer 252 growth may be performed, and as noted above it may be done in situ in the same chamber as the well formation in some implementations. Here again, the MST 125 formation may be with or without a PGA. Thick oxide 213 deposition may then be performed (FIG. 8E), followed by removal where the gates are to be formed, pre-cleaning and thin gate oxide 207 growth (FIG. 8F), and gate electrode plus source/drain formation (similar to FIGS. 5A and 5B).

Many modifications and other embodiments of the invention will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A method for making a semiconductor device comprising:
forming spaced apart shallow trench isolation (STI) regions in a semiconductor layer;
etching first portions of the semiconductor layer between adjacent ones of the STI regions to an etch depth;
performing a well implant in the first portions of the semiconductor layer;
forming respective superlattices on the etched first portions of the semiconductor layer between the adjacent ones of STI regions and with a height not greater than the etch depth, each superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
forming respective spaced apart source and drain regions associated with each superlattice; and
forming a respective gate above each superlattice.

2. The method of claim 1 where each superlattice defines a channel region between adjacent ones of the source and drain regions.

3. The method of claim 1 comprising forming a mask over at least some of the STI regions and second portions of the semiconductor layer prior to etching.

4. The method of claim 1 comprising:
forming respective first oxide portions over the superlattices; and
forming respective second oxide portions over the second portions of the semiconductor layer, the second oxide portions being thicker than the first oxide portions.

5. The method of claim 1 wherein the etch depth is 60 nm or less.

6. The method of claim 1 further comprising growing a respective semiconductor buffer layer on each of the first portions of the semiconductor layer after performing the well implant.

7. The method of claim 6 comprising performing another well implant in the semiconductor buffer layers prior to forming the superlattices.

8. The method of claim 1 wherein etching comprises reactive ion etching.

9. The method of claim 1 comprising performing a post etch cleaning after etching.

10. The method of claim 1 wherein the base semiconductor monolayers comprise silicon.

11. The method of claim 1 wherein the at least one non-semiconductor monolayer comprises oxygen.

12. A method for making a semiconductor device comprising:
forming spaced apart shallow trench isolation (STI) regions in a semiconductor layer;
etching first portions of the semiconductor layer between adjacent ones of the STI regions to an etch depth;
performing a well implant in the first portions of the semiconductor layer;
growing a respective semiconductor buffer layer in each of the etched portions of the semiconductor layer;
forming respective superlattices on each semiconductor buffer between the adjacent ones of STI regions and with a height not greater than the etch depth, each superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
forming respective spaced apart source and drain regions associated with each superlattice, each superlattice defining a channel region between adjacent ones of the source and drain regions; and
forming a respective gate above each superlattice.

13. The method of claim 12 comprising forming a mask over at least some of the STI regions and second portions of the semiconductor layer prior to etching.

14. The method of claim 12 comprising:
forming respective first oxide portions over the superlattices; and
forming respective second oxide portions over the second portions of the semiconductor layer, the second oxide portions being thicker than the first oxide portions.

15. The method of claim 12 comprising performing another well implant in the semiconductor buffer layers prior to forming the superlattices.

16. A method for making a semiconductor device comprising:
forming spaced apart shallow trench isolation (STI) regions in a semiconductor layer;
etching first portions of the semiconductor layer between adjacent ones of the STI regions to an etch depth;
performing a well implant in the first portions of the semiconductor layer;
forming respective superlattices on the etched first portions of the semiconductor layer between the adjacent ones of STI regions and with a height not greater than the etch depth, each superlattice comprising a plurality of stacked groups of layers, each group of layers comprising a plurality of stacked base silicon monolayers defining a base silicon portion, and at least one oxygen monolayer constrained within a crystal lattice of adjacent base silicon portions;
forming respective spaced apart source and drain regions associated with each superlattice; and
forming a respective gate above each superlattice.

17. The method of claim 16 where each superlattice defines a channel region between adjacent ones of the source and drain regions.

18. The method of claim 16 comprising forming a mask over at least some of the STI regions and second portions of the semiconductor layer prior to etching.

19. The method of claim 16 comprising:
forming respective first oxide portions over the superlattices; and
forming respective second oxide portions over the second portions of the semiconductor layer, the second oxide portions being thicker than the first oxide portions.

20. The method of claim 16 further comprising growing a respective semiconductor buffer layer on each of the first portions of the semiconductor layer after performing the well implant; and performing another well implant in the semiconductor buffer layers prior to forming the superlattices.
